(19) United States
(12) Patent Application Publication
(10) Pub. No.: US 2026/0171359 A1
(43) Pub. Date: Jun. 18, 2026

(54) SYSTEMS AND METHODS FOR DRIVING PASSIVATION TO INCREASE AN ETCH RATE

(71) Applicant: Lam Research Corporation, Fremont, CA (US)

(72) Inventors: Amit MUKHOPADHYAY, Fremont, CA (US); Gregory Clinton VEBER, San Diego, CA (US); Qing XU, Fremont, CA (US); Merrett WONG, Palo Alto, CA (US)

(21) Appl. No.: 19/128,914

(22) PCT Filed: Nov. 2, 2023
(86) PCT No.: PCT/US2023/078563

§ 371 Date: May 9, 2025

Related U.S. Application Data
(60) Provisional application No. 63/425,995, filed on Nov. 16, 2022.

(51) Int. Cl. H01J 37/32; H10P 50/26; H10P 50/28; H10P 72/00

(52) U.S. Cl. CPC H01J 37/32146; H01J 37/32183; H10P 72/0421; H01J 2237/334; H10P 50/268; H10P 50/283

(57) ABSTRACT

Systems and methods for driving passivation to increase a rate of etching a substrate are described. One of the methods includes generating a kilohertz radio frequency (RF) signal and generating a megahertz RF signal. The method includes pulsing, in a synchronized manner, the kilohertz and megahertz RF signals to transition to a first state. The method also includes transitioning, in a synchronized manner, the kilohertz and megahertz RF signals from the first state to a second state to achieve passivation on a mask layer of the substrate. The method includes pulsing, in a synchronized manner, the kilohertz and megahertz RF signals from the second state to a third state to drive the passivation from a neck of the substrate to a pillar of the substrate. The method includes transitioning, in a synchronized manner, the kilohertz and megahertz RF signals from the third state to a fourth state.

### FIELD

The present embodiments relate to systems and methods for driving passivation to increase an etch rate.

### BACKGROUND

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

In a plasma tool, a radio frequency (RF) generator is provided. The plasma tool further includes a match and a plasma chamber. The RF generator is coupled via the match to the plasma chamber. A semiconductor wafer is placed in the plasma chamber for being processed. It is important that the semiconductor wafer be processed at a desired rate.

### SUMMARY

Embodiments of the disclosure provide systems, apparatus, methods and computer programs for driving passivation to increase an etch rate. It should be appreciated that the present embodiments can be implemented in numerous ways, e.g., a process, an apparatus, a system, a device, or a method on a computer readable medium. Several embodiments are described below.

In some embodiments, during high aspect ratio (HAR) etch, scaling of a critical dimension (CD), such as widths of features of a substrate, is important. The scaling is important with an increase in depths of the features while maintain widths of the features substantially constant. Multi-state pulsing, such as four or more state pulsing, is utilized to strategically deposit a polymer on top of an existing mask material of a mask layer to achieve passivation and protect the mask layer from eroding to enhance mask selectivity, or deposit the passivation within the features to protect CDs and overcome HAR-related challenges. Specifically, different mask shapes are tailored to precisely impart desired benefits in HAR etch processing. For example, the enhanced mask selectivity enables longer over-etch (OE) and improves a profile taper or shrinks mask height, or shrunk CDs improve the profile taper and opens process space for later steps. The profile is a profile of each feature of the substrate. For example, the profile is a bow CD of a neck of each feature, or a bottom CD of a pillar of each feature, or a taper of each feature, or a defect formation within each feature, or a combination thereof.

In one embodiment, the systems and methods, described herein, increase mask selectivity by tuning a power pulse shape, which prevents any integration or contamination or device reliability issues. Pulse shape and width optimization results in profile or mask selectivity improvement.

In an embodiment, the multistate pulsing, in which four or more states, are applied improves the profile or increases the mask selectivity with trade-off mitigation. For example, a first state, such as a high state, is applied for etching. The high state, such as a state S1, is followed immediately by a second state, such as a low state. The low state, such as a state S0, is applied to deposit passivation on top of a mask layer and on sidewalls of the mask layer. The passivation becomes integral to the mask layer. The second state is immediately followed by a third state to shape the mask layer, e.g., the passivation integral with the mask layer, to enable profile improvement. A fourth state that immediately follows the third state increases density of plasma to maintain the etch and mitigate any trade-offs. The first through fourth states are applied during a clock cycle of a clock signal and are repeated during each additional clock cycle of the clock signal.

The high state has a high level of power to etch structures, such as the features, of the substrate. Both high and low frequency powers, when used, are optimized towards a higher end of the high level to enhance a vertical to lateral etch rate. The vertical etch rate facilitates etching the features in a vertical direction and the lateral etch rate facilitates etching the features in a horizontal direction. The high level of the low frequency power ranges from 1 kilowatts (kW) to 100 kW. The low state of the low frequency power and of the high frequency power results in the passivation, such as deposition, of the polymer on the sidewalls and the top of the mask layer. The passivation facilitates protection of the sidewalls and decrease in an etch rate of etching the mask layer, resulting in max CD shrink and mask selectivity increase. The CD shrinks at a neck of the substrate, The low state of the low and high frequency powers has a power level that ranges from 0 watts powers to as high as 2 kW to 5 kW.

The third state facilitates mask shaping. With the power level of the low state, the passivation is mainly at the top of the mask layer to increase the mask selectivity. The third state has a higher amount of power than that of the low state to change a shape of the passivation at the top and at the neck. This change in the shape results in deposition deeper into the features and protection of the sidewalls of the features.

The fourth state enhances a life of the plasma by enhancing a density of the plasma. Otherwise, the plasma can turn off and result in slower etch rates. A power level of the fourth state ranges from an intermediate level to a level that is at a lower end of the range of the power level for the high state. For example, the power level of the fourth state ranges from 300 watts to 1 kW.

In an embodiment, a shape of each pulse for each state of the multistate pulsing and a duty cycle, such as a width, of the pulse is optimized to maximize the benefits, described herein. Also, the duty cycle is optimized by optimizing the etch rate in a repeated manner, and matching on and off times between different pulse shapes. Additional pulse steps can also be used to improve the profile further.

In an embodiment, a method for driving passivation to increase a rate of etching a substrate is described. The method includes generating a kilohertz radio frequency (RF) signal and generating a megahertz RF signal. The method further includes supplying the kilohertz and megahertz RF signals to an impedance matching circuit coupled to an electrode of a plasma chamber. During a clock cycle of a clock signal, the method includes pulsing, in a synchronized manner, the kilohertz and megahertz RF signals to transition to a first state to etch the substrate. The method further includes maintaining the kilohertz and megahertz RF signals in the first state for a first predetermined time period. The method also includes transitioning, in a synchronized manner, the kilohertz and megahertz RF signals from the first state to a second state to achieve passivation on a side wall and a top surface of a mask layer of the substrate. The method includes maintaining the kilohertz and megahertz RF signals in the second state for a second predetermined time period that is greater than the first predetermined time period. During the second state, a power level of the kilohertz RF signal is less than a power level of the kilohertz RF signal during the first state and a power level of the megahertz RF signal is less than a power level of the megahertz RF signal during the first state. The method includes pulsing, in a synchronized manner, the kilohertz and megahertz RF signals from the second state to a third state to drive the passivation from a neck of the substrate to a pillar of the substrate. The method also includes maintaining the kilohertz and megahertz RF signals in the third state for a third predetermined time period that is substantially equal to the first predetermined time period. During the third state, a power level of the kilohertz RF signal is greater than the power level of the kilohertz RF signal during the second state and a power level of the megahertz RF signal is greater than the power level of the megahertz RF signal during the second state. The method includes transitioning, in a synchronized manner, the kilohertz and megahertz RF signals from the third state to a fourth state to reduce the passivation from the neck of the substrate. The method includes maintaining the kilohertz and megahertz RF signals in the fourth state for a fourth predetermined time period that is greater than the third predetermined time period. During the fourth state, a power level of the kilohertz RF signal is less than the power level of the kilohertz RF signal during the third state and a power level of the megahertz RF signal is less than the power level of the megahertz RF signal during the third state.

In an embodiment, a controller for driving passivation to increase a rate of etching a substrate is described. The controller includes a processor and a memory device coupled to the processor. The processor controls a first RF generator to generate a kilohertz RF signal and controls a second RF generator to generate a megahertz RF signal. During a clock cycle of a clock signal, the processor controls the first and second RF generators to pulse, in a synchronized manner, the kilohertz and megahertz RF signals to transition to a first state. The processor further controls the first and second RF generators to maintain the kilohertz and megahertz RF signals in the first state for a first predetermined time period. The processor controls the first and second RF generators to transition, in a synchronized manner, the kilohertz and megahertz RF signals from the first state to a second state. The processor also controls the first and second RF generators to maintain the kilohertz and megahertz RF signals in the second state for a second predetermined time period that is greater than the first predetermined time period. During the second state, a power level of the kilohertz RF signal is less than a power level of the kilohertz RF signal during the first state and a power level of the megahertz RF signal is less than a power level of the megahertz RF signal during the first state. The processor controls the first and second RF generators to pulse, in a synchronized manner, the kilohertz and megahertz RF signals from the second state to a third state. The processor also controls the first and second RF generators to maintain the kilohertz and megahertz RF signals in the third state for a third predetermined time period that is substantially equal to the first predetermined time period. During the third state, a power level of the kilohertz RF signal is greater than the power level of the kilohertz RF signal during the second state and a power level of the megahertz RF signal is greater than the power level of the megahertz RF signal during the second state. The processor controls the first and second RF generators to transition, in a synchronized manner, the kilohertz and megahertz RF signals from the third state to a fourth state. The processor controls the first and second RF generators to maintain the kilohertz and megahertz RF signals in the fourth state for a fourth predetermined time period that is greater than the third predetermined time period. During the fourth state, a power level of the kilohertz RF signal is less than the power level of the kilohertz RF signal during the third state and a power level of the megahertz RF signal is less than the power level of the megahertz RF signal during the third state.

In one embodiment, a system for driving passivation to increase a rate of etching a substrate is described. The system includes a first RF generator that generates a kilohertz RF signal and a second RF generator that generates a megahertz RF signal. The system further includes an impedance matching circuit coupled to the first and second RF generators to receive the kilohertz and megahertz RF signals to output a modified RF signal. The system includes a plasma chamber coupled to the impedance matching circuit to receive the modified RF signal. The system includes a controller coupled to the first and second RF generators. During a clock cycle of a clock signal, the controller controls the first and second RF generators to pulse, in a synchronized manner, the kilohertz and megahertz RF signals to transition to a first state. Moreover, the controller controls the first and second RF generators to maintain the kilohertz and megahertz RF signals in the first state for a first predetermined time period. The controller controls the first and second RF generators to transition, in a synchronized manner, the kilohertz and megahertz RF signals from the first state to a second state. The controller also controls the first and second RF generators to maintain the kilohertz and megahertz RF signals in the second state for a second predetermined time period that is greater than the first predetermined time period. During the second state, a power level of the kilohertz RF signal is less than a power level of the kilohertz RF signal during the first state and a power level of the megahertz RF signal is less than a power level of the megahertz RF signal during the first state. The controller controls the first and second RF generators to pulse, in a synchronized manner, the kilohertz and megahertz RF signals from the second state to a third state. Furthermore, the controller controls the first and second RF generators to maintain the kilohertz and megahertz RF signals in the third state for a third predetermined time period that is substantially equal to the first predetermined time period. During the third state, a power level of the kilohertz RF signal is greater than the power level of the kilohertz RF signal during the second state and a power level of the megahertz RF signal is greater than the power level of the megahertz RF signal during the second state. The controller controls the first and second RF generators to transition, in a synchronized manner, the kilohertz and megahertz RF signals from the third state to a fourth state. The controller controls the first and second RF generators to maintain the kilohertz and megahertz RF signals in the fourth state for a fourth predetermined time period that is greater than the third predetermined time period. During the fourth state, a power level of the kilohertz RF signal is less than the power level of the kilohertz RF signal during the third state and a power level of the megahertz RF signal is less than the power level of the megahertz RF signal during the third state.

Some advantages of the herein described systems and methods include increasing a rate of processing the substrate. By driving the passivation downwards during the third state, there is an increase in the etch rate. In addition, the sidewalls of the features are protected from being etched after the passivation is driven down to form a passivation layer on the sidewalls. By driving the passivation downwards, there is an increase in the vertical etch rate and a decrease in the lateral etch rate.

Further advantages of the herein described systems and methods include protecting the plasma from being extinguished during the third and fourth states. Without the third state, the plasma can extinguish, which decreases the etch rate. By providing the third state, chances of the plasma being extinguished are reduced. Also, due to the third state, a power level of the fourth state increases compared to when the third state is not applied. The increase in the power level of the fourth state further reduces the chances of the plasma from being extinguished.

Other aspects will become apparent from the following detailed description, taken in conjunction with the accompanying drawings.

### BRIEF DESCRIPTION OF THE DRAWINGS

The embodiments may best be understood by reference to the following description taken in conjunction with the accompanying drawings.

FIG. 1 is a diagram of an embodiment of a system to illustrate processing of a substrate by using multiple states of radio frequency (RF) signals.

FIG. 2 is an embodiment of a graph to illustrate the multiple states of power levels of the RF signals.

FIG. 3A is a side view of an embodiment of a portion of a substrate to illustrate an effect of application of a first state of a first one of the RF signals and a first state of a second one of the RF signals.

FIG. 3B is a side view of an embodiment of a portion of the substrate to illustrate an effect of application of a second state of the first one of the RF signals and a second state of the second one of the RF signals.

FIG. 3C is a side view of an embodiment of a portion of the substrate to illustrate an effect of application of a third state of the first one of the RF signals and a third state of the second one of the RF signals.

FIG. 3D is a side view of an embodiment of a portion of the substrate to illustrate an effect of application of a fourth state of the first one of the RF signals and a fourth state of the second one of the RF signals.

FIG. 4 is a diagram of an embodiment of a system to illustrate an operation of each RF generator of the system of FIG. 1.

### DETAILED DESCRIPTION

The following embodiments describe systems and methods for driving passivation to increase an etch rate. It will be apparent that the present embodiments may be practiced without some or all of these specific details. In other instances, well known process operations have not been described in detail in order not to unnecessarily obscure the present embodiments.

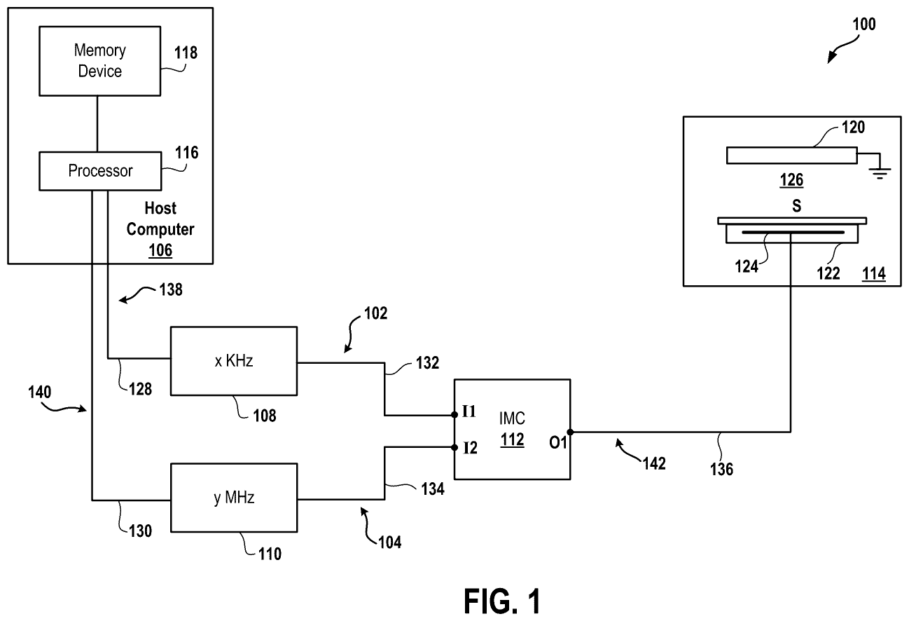

FIG. 1 is a diagram of an embodiment of a system 100 to illustrate processing of a substrate S by using multiple states of radio frequency (RF) signals 102 and 104. The system 100 includes a host computer 106, an RF generator 108, another RF generator 110, and impedance matching circuit (IMC) 112, and a plasma chamber 114. The host computer 106 includes a processor 116 and a memory device 118. The plasma chamber 114 includes an upper electrode 120 and a substrate support 122, such as an electrostatic chuck (ESC). The substrate support 122 includes a lower electrode 124.

An example of the substrate S is a semiconductor wafer. To illustrate, the substrate S is used to fabricate a 3D memory, a 3D NAND, or a dynamic random access memory (DRAM) capacitor. Examples of the host computer 106 include a desktop computer, a controller, a tablet, a server, a laptop computer, a controller, and a smart phone. A controller, as used herein, includes one or more processors and one or more memory devices. The one or more processors of the controller are coupled to the one or more memory devices of the controller. As used herein, a processor is an application specific integrated circuit (ASIC), or a digital signal processor, or a programmable logic device (PLD), or a central processing unit (CPU), or a microprocessor, or an integrated controller, or a microcontroller. Examples of a memory device, as used herein, include a random access memory (RAM) and a read-only memory (ROM). To illustrate, a memory device is a flash memory, a hard disk, or a storage device, etc. A memory device is an example of a computer-readable medium.

An example of the RF generator 108 is an RF generator having a low frequency of operation of x kilohertz (kHz), such as 100 kHz or 400 kHz. Also, an example of the RF generator 110 is an RF generator having a high frequency of operation of y megahertz (MHz), such as 60 MHz or 27 MHz. The IMC 112 includes a network of electronic components, such as capacitors or inductors or a combination thereof, coupled to each other. For example, the IMC 112 includes one or more series circuits and one or more shunt circuits. Each of the series circuits is a capacitor or an inductor and each of the shunt circuits is a capacitor or an inductor.

The plasma chamber 114 is a capacitively coupled plasma (CCP) chamber. The substrate support 122 has embedded therein the lower electrode 124. Each of the upper electrode 120 and the lower electrode 124 is fabricated from a metal, such as aluminum or an alloy of aluminum. The substrate S is placed on a top surface of the substrate support 122 and within a gap 126 formed between a bottom surface of the upper electrode 120 and the top surface of the substrate support 122.

The processor 116 is coupled to the RF generator 108 via a transfer cable 128 and is coupled to the RF generator 110 via another transfer cable 130. An example of a transfer cable is a cable for serial transfer of data, or parallel transfer of data, or a transfer of data via a Universal Serial Bus (USB) protocol. The RF generator 108 is coupled to an input Il of the IMC 112 via an RF cable 132 and is coupled to another input I2 of the IMC 112 via another RF cable 134. An output O1 of the IMC 112 is coupled to the lower electrode 124 via an RF transmission line 136. The upper electrode 120 is coupled to a ground potential.

The processor 116 generates a recipe signal 138 and sends the recipe signal 138 via the transfer cable 128 to the RF generator 108. As an example, the recipe signal 138 includes data for generating the RF signal 102. To illustrate, the recipe signal 138 includes a frequency level of the RF signal 102, a power level of a state S1 of the RF signal 102, a power level of a state S0 of the RF signal 102, a power level of a state SB of the RF signal 102, and a power level of a state SA of the RF signal 102. Moreover, the recipe signal 138 includes a duty cycle for which the power level of the state S1 of the RF signal 102 is to be generated by the RF generator 108, a duty cycle for which the power level of the state S0 of the RF signal 102 is to be generated by the RF generator 108, a duty cycle for which the power level of the state SB of the RF signal 102 is to be generated by the RF generator 108, and a duty cycle for which the power level of the state SA of the RF signal 102 is to be generated by the RF generator 108.

As an example, each duty cycle is a time interval, such as a time period, of a power level of an RF signal for which a corresponding, such as a respective, state of the RF signal is to be generated by an RF generator. For example, a duty cycle of the power level of the state S1 of the RF signal 102 is a time interval for which the power level is to be generated by the RF generator 108. The duty cycle is to be generated during each clock cycle of a clock signal, such as a digital pulse signal that periodically transitions between a logic level 1 and a logic level 1. As an illustration, the clock signal having the multiple clock cycles is generated by the processor 116, sent via the transfer cable 128 to the RF generator 108, and sent via the transfer cable 130 to the RF generator 110 to synchronize operations of the host computer 106, and the RF generators 108 and 110 with each other.

Moreover, as an example, a power level of a state includes one or more power values, such as magnitudes, within a predetermined power range of the state. For example, the power level is a statistical value, such as an average or median, of multiple power values within the predetermined power range. Also, as an example, a frequency level of an RF signal includes one or more frequency values within a predetermined frequency range. For example, the frequency level is a statistical value, such as an average or median or a frequency of operation, of multiple frequency values within the predetermined frequency range.

Similarly, the processor 116 generates a recipe signal 140 and sends the recipe signal 140 via the transfer cable 130 to the RF generator 110. As an example, the recipe signal 140 includes data for generating the RF signal 104. To illustrate, the recipe signal 140 includes a frequency level of the RF signal 104, a power level of a state S1 of the RF signal 104, a power level of a state S0 of the RF signal 104, a power level of a state SB of the RF signal 104, and a power level of a state SA of the RF signal 104. Moreover, the recipe signal 140 includes a duty cycle for which the power level of the state S1 of the RF signal 104 is to be generated by the RF generator 110, a duty cycle for which the power level of the state S0 of the RF signal 104 is to be generated by the RF generator 110, a duty cycle for which the power level of the state SB of the RF signal 104 is to be generated by the RF generator 110, and a duty cycle for which the power level of the state SA of the RF signal 104 is to be generated by the RF generator 110. As an example, each duty cycle of a power level of the RF signal 104 is a time interval for which a corresponding, such as a respective, state of the RF signal 104 is to be generated by the RF generator 110. The duty cycle is to be generated during each clock cycle of the clock signal.

After receiving the recipe signal 138, the RF generator 108 stores the data for generating the RF signal 102. For example, one or more processors of the RF generator 108 store the data for generating the RF signal 102 in one or more memory devices of the RF generator 108. Similarly, after receiving the recipe signal 140, the RF generator 110 stores the data for generating the RF signal 104. For example, one or more processors of the RF generator 110 store the data for generating the RF signal 104 in one or more memory devices of the RF generator 110.

The processor 116 generates a trigger signal at a time of start of a clock cycle of the clock signal, sends the trigger signal via the transfer cable 128 to the RF generator 108, and sends the trigger signal via the transfer cable 130 to the RF generator 110. In response to receiving the trigger signal from the processor 116 via the transfer cable 128, the one or more processors of the RF generator 108 access the data for generating the RF signal 102 from the one or more memory devices of the RF generator 108 to generate the RF signal 102 according to the data. Also, in response to receiving a trigger signal from the processor 116 via the transfer cable 130, the one or more processors of the RF generator 110 access the data for generating the RF signal 104 from the one or more memory devices of the RF generator 110 to generate the RF signal 104 according to the data.

The RF signal 102 is supplied from the RF generator 108 via the RF cable 132 to the input I1 of the IMC 112 and the RF signal 104 is supplied from the RF generator 110 via the RF cable 134 to the input I2 of the IMC 112. The IMC 112 modifies an impedance of the RF signal 102 to match an impedance of a load coupled to the output O1 of the IMC 112 with an impedance of a source coupled to the input I1 to output a first modified RF signal. An example of the source coupled to the input I1 includes the RF cable 132 and the RF generator 108. An example of the load coupled to the output O1 includes the RF transmission line 136 and the plasma chamber 114. Also, the IMC 112 modifies an impedance of the RF signal 104 to match an impedance of the load coupled to the output O1 of the IMC 112 with an impedance of a source coupled to the input I2 to output a second modified RF signal. An example of the source coupled to the input I2 includes the RF cable 134 and the RF generator 110. The IMC 112 combines, such as sums, the first and second modified RF signals to provide a modified RF signal 142 to the output O1.

The modified RF signal 142 is sent via the RF transmission line 136 to the lower electrode 124. In addition, when one or more process gases are supplied to the gap 126 in addition to supplying the modified RF signal 142, plasma is stricken or maintained within the gap 126 to process the substrate S. Examples of the one or more process gases include an oxygen-containing gas, such as O₂. Other examples of the one or more process gases include a fluorine-containing gas, e.g., tetrafluoromethane (CF₄), sulfur hexafluoride (SF₆), hexafluoroethane (C₂F₆), etc. Examples of processing the substrate S include depositing a material on the substrate, etching the substrate, and cleaning the substrate.

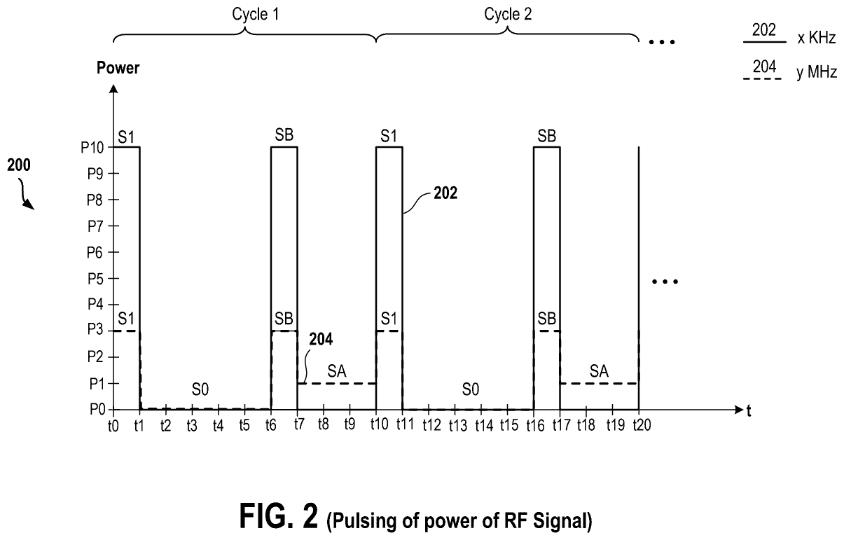

FIG. 2 is an embodiment of a graph 200 to illustrate the multiple states of the power levels of the RF signal 102 (FIG. 1) and the multiple states of the power levels of the RF signal 104 (FIG. 1). The graph 200 plots values of the power levels of the RF signals 102 and 104 on a y-axis and time t on an x-axis. For example, the graph 200 includes a plot 202, in solid lines, of values of power levels of the RF signal 102 versus the time t and includes a plot 204, in dashed lines, of values of power levels of the RF signal 104 versus the time t.

The power levels range in an increasing manner from a power level P0 to a power level P10 and the time t ranges progressively from a time t0 to a time t20. For example, a time interval between the times t0 and t10 includes times t1, t2, t3, t4, t5, t6, t7, t8, and t9. In the example, the time t10 occurs after the time t9, which occurs after the time t8 and so on until the time t1 occurs after the time t0. In the example, it should be noted that time intervals between any two consecutive times are equal. To illustrate, a time interval between the times t2 and t1 is equal to a time interval between the times t3 and t2. Also, in the example, various power levels P2, P3, P4, P5, P6, P7, P8, and P9 lie between the power levels P0 and P10. To illustrate, the power level P10 is greater than the power level P9, the power level P9 is greater than the power level P8, and so on until the power level P1 is greater than the power level P0. As another illustration, the power level P1 is greater than the power level P0 and the power level P3 is greater than the power level P1. Also, in the illustration, the power level P10 is greater than the power level P3.

The clock signal has multiple cycles, such as a cycle 1 and a cycle 2. The cycle 1 extends or occurs from the time t0 to the time t10, and the cycle 2 occurs from the time t10 to the time t20. The cycle 2 consecutively follows the cycle 1.

At the time t0, the power level of the RF signal 102 increases from the power level P0 to the power level P10 to achieve the state S1 of the RF signal 102. As an example, the power level P10 is a value, such as a magnitude, within a range from 1 kilowatts (kW) to 100 kW. To illustrate, the power level P10 has a power value of 1 kW. The power level of the RF signal 102 remains at the state S1, such as the power level P10, from the time t0 to the time t1. The time interval between the times t0 and t1 is an example of a predetermined time interval and is the duty cycle of the state S1 of the RF signal 102. As an example, the duty cycle of the state S1 of the RF signal 102 is a time interval within a range from 5 percent (%) to 20 percent of the cycle 1 of the clock signal.

Moreover, at the time t1, the power level of the RF signal 102 decreases from the power level P10 to the power level P0 to achieve the state S0 of the RF signal 102. As an example, the power level P0 is a value, such as a magnitude, that is substantially zero. To illustrate, the power level P0 is a value that lies within a range from 0 watts (W) to 200 watts. To further illustrate, the power level P0 is zero watts. The power level of the RF signal 102 remains at the state S0, such as the power level P0, from the time t1 to the time t6. The time interval between the times t1 and t6 is an example of a predetermined time interval and is the duty cycle of the state S0 of the RF signal 102 and is greater than the time interval between the times t0 and t1 of the duty cycle of the state S1 of the RF signal 102. As an example, the duty cycle of the state S0 of the RF signal 102 is a time interval within a range from 20 percent to 60 percent of the cycle 1 of the clock signal.

Furthermore, at the time t6, the power level of the RF signal 102 increases from the power level P0 to the power level P10 to achieve the state SB of the RF signal 102. The power level of the RF signal 102 remains at the state SB, such as the power level P10, from the time t6 to the time t7. The time interval between the times t6 and t7 is an example of a predetermined time interval and is the duty cycle of the state SB of the RF signal 102. As an example, the duty cycle of the state SB of the RF signal 102 is substantially equal to the duty cycle of the state S1 of the RF signal 102. To illustrate, the duty cycle of the state SB of the RF signal 102 is a time interval within a range from 5 percent to 20 percent of the cycle 1 of the clock signal. To further illustrate, the duty cycle of the state SB of the RF signal 102 is equal to the duty cycle of the state S1 of the RF signal 102. As another illustration, the duty cycle of the state SB of the RF signal 102 is greater than or less than the duty cycle of the state S1 of the RF signal 102 by a predetermined percentage, such as within 5 percent, of the duty cycle of the state S1 of the RF signal 102.

Also, at the time t7, the power level of the RF signal 102 decreases from the power level P10 to the power level P0 to achieve the state SA of the RF signal 102. The power level of the RF signal 102 remains at the state SA, such as the power level P0, from the time t7 to the time t10. An example of the power level P0 of the RF signal 102 during the state SB is zero watts. The time interval between the times t7 and t10 is an example of a predetermined time interval, is the duty cycle of the state SA of the RF signal 102, and is greater than the time interval between the times t6 and t7 of the duty cycle of the state SB of the RF signal 102. As an example, the duty cycle of the state SA of the RF signal 102 is a time interval within a range from 20 percent to 60 percent of the cycle 1 of the clock signal. In the same manner as that described herein with respect to the cycle 1, the states S1, S0, SB, and SA of the RF signal 102 repeat during each additional cycle, such as the cycle 2, of the clock signal.

Moreover, at the time t0, the power level of the RF signal 104 increases from the power level P0 to the power level P3 to achieve the state S1 of the RF signal 104. As an example, when both the RF signals 102 and 104 transition to the states S1 at the time t0, the RF signals 102 and 104 are pulsed in a synchronized manner to achieve the state S1. Also, as an example, the power level P3 is a value, such as a magnitude, within a range from 1 kilowatts to 11 kilowatts. To illustrate, the power level P3 has a power value of 1 kilowatts. The power level of the RF signal 104 remains at the state S1, such as the power level P3, from the time t0 to the time t1. The time interval between the times t0 and t1 is the duty cycle of the state S1 of the RF signal 104. As an example, the duty cycle of the state S1 of the RF signal 104 is a time interval within a range from 5 percent to 20 percent of the cycle 1 of the clock signal.

Moreover, at the time t1, the power level of the RF signal 104 decreases from the power level P3 to the power level P0 to achieve the state S0 of the RF signal 104. As an example, when both the RF signals 102 and 104 transition to the states S0 at the time t1, the RF signals 102 and 104 are pulsed in a synchronized manner to achieve the state S0. The power level of the RF signal 104 remains at the state S0, such as the power level P0, from the time t1 to the time t6. The time interval between the times t1 and t6 is the duty cycle of the state S0 of the RF signal 104 and is greater than the time interval between the times t0 and t1 of the duty cycle of the state S1 of the RF signal 104. As an example, the duty cycle of the state S0 of the RF signal 104 is a time interval within a range from 20 percent to 60 percent of the cycle 1 of the clock signal.

Furthermore, at the time t6, the power level of the RF signal 104 increases from the power level P0 to the power level P3 to achieve the state SB of the RF signal 104. As an example, when both the RF signals 102 and 104 transition to the states SB from the states S0 at the time t6, the RF signals 102 and 104 are pulsed in a synchronized manner to achieve the state SB. The power level of the RF signal 104 remains at the state SB, such as the power level P3, from the time t6 to the time t7. The time interval between the times t6 and t7 is equal to the time interval between the times t0 and t1. The time interval between the times t6 and t7 is the duty cycle of the state SB of the RF signal 104. As an example, the duty cycle of the state SB of the RF signal 104 is substantially equal to the duty cycle of the state S1 of the RF signal 104. To illustrate, the duty cycle of the state SB of the RF signal 104 is a time interval within a range from 5 percent to 20 percent of the cycle 1 of the clock signal. To further illustrate, the duty cycle of the state SB of the RF signal 104 is equal to the duty cycle of the state S1 of the RF signal 104. As another illustration, the duty cycle of the state SB of the RF signal 104 is greater than or less than the duty cycle of the state S1 of the RF signal 104 by a predetermined percentage, such as within 5 percent, of the duty cycle of the state S1 of the RF signal 104.

Also, at the time t7, the power level of the RF signal 104 decreases from the power level P3 to the power level P1 to achieve the state SA of the RF signal 104. As an example, when both the RF signals 102 and 104 transition to the states SA from the states SB at the time t7, the RF signals 102 and 104 are pulsed in a synchronized manner to achieve the state SB. As an example, the power level P1 includes a value that is within a range from 200 watts to 1000 watts. To illustrate, the power level P1 is 200 watts. The power level of the RF signal 104 remains at the state SA, such as the power level P1, from the time t7 to the time t10. The time interval between the times t7 and t10 is the duty cycle of the state SA of the RF signal 104 and is greater than the time interval between the times t6 and t7 of the duty cycle of the state SB of the RF signal 104. As an example, the duty cycle of the state SA of the RF signal 104 is a time interval within a range from 20 percent to 60 percent of the cycle 1 of the clock signal. In the same manner as that described herein with respect to the cycle 1, the states S1, S0, SB, and SA of the RF signal 104 repeat during each additional cycle, such as the cycle 2, of the clock signal.

It should be noted that a sum of the duty cycles of the states S1, S0, SB, and SA of the RF signal 102 equals to 100 percent of each cycle of the clock signal. For example, when the duty cycle of the state S1 of the RF signal 102 is 5 percent of the cycle 1, the duty cycle of the state S0 of the RF signal 102 is 60 percent of the cycle 1, and the duty cycle of the state SB of the RF signal 102 is 5 percent of the cycle 1, the duty cycle of the state SA of the RF signal 102 is 30 percent of the cycle 1.

Similarly, a sum of the duty cycles of the states S1, S0, SB, and SA of the RF signal 104 equals to 100 percent of each cycle of the clock signal. For example, when the duty cycle of the state S1 of the RF signal 104 is 5 percent of the cycle 1, the duty cycle of the state S0 of the RF signal 104 is 60 percent of the cycle 1, and the duty cycle of the state SB of the RF signal 104 is 5 percent of the cycle 1, the duty cycle of the state SA of the RF signal 104 is 30 percent of the cycle 1.

It should further be noted that without inclusion of the state SB of the RF signal 104, the power level of a tertiary state of an RF signal (not shown) supplied by the RF generator 110 lies in a range from 0 watts to 200 watts. The tertiary state immediately follows a secondary state of the RF signal (not shown) and the secondary state immediately follows a primary state of the RF signal (not shown). Each of the primary, secondary, and tertiary states is a different power level of the RF signal (not shown), and is repeated during each cycle of the clock signal. By including the state SB of the RF signal 104, the power level P1 of the state SA of the RF signal 104 lies within the range from 200 watts to 1000 watts. The range from 200 watts to 1000 watts is increased compared to the range from 0 watts to 200 watts. The increased range reduces an amount of time for which the state SA of the RF signal 104 occurs. The amount time is reduced compared to an amount of time for which the tertiary state of the RF signal (not shown) is applied to decrease an amount of time in which the substrate S is processed. With the increased range, there is an increase in ion density of the plasma. The ion density is increased compared to an amount of ion density when the range from 0 watts to 200 watts is applied. The increase in the ion density increases a stability of the plasma and the plasma does not extinguish during the processing of the substrate S. Moreover, with the increased range, passivation at a neck of the substrate S is removed quicker compared to when the range from 0 watts to 200 watts is used.

In an embodiment, both the RF signals 102 and 104 transition to the states S1 from the states SA of a preceding cycle, such as a cycle 0 of the clock signal, within a predetermined time interval. The preceding cycle precedes the cycle 1 of the clock signal. When both the RF signals 102 and 104 transition to the states S1 within the predetermined time interval, the RF signals 102 and 104 are pulsed in the synchronized manner to achieve the state S1.

In one embodiment, both the RF signals 102 and 104 transition from the states S1 to the states S0 within a predetermined time interval. When both the RF signals 102 and 104 transition to the states S0 within the predetermined time interval, the RF signals 102 and 104 are pulsed in the synchronized manner to achieve the state S0.

In one embodiment, both the RF signals 102 and 104 transition from the states S0 to the states SB within a predetermined time interval. When both the RF signals 102 and 104 transition to the states SB within the predetermined time interval, the RF signals 102 and 104 are pulsed in the synchronized manner to achieve the state SB.

In one embodiment, both the RF signals 102 and 104 transition from the states SB to the states SA within a predetermined time interval. When both the RF signals 102 and 104 transition to the states SA within the predetermined time interval, the RF signals 102 and 104 are pulsed in the synchronized manner to achieve the state SA.

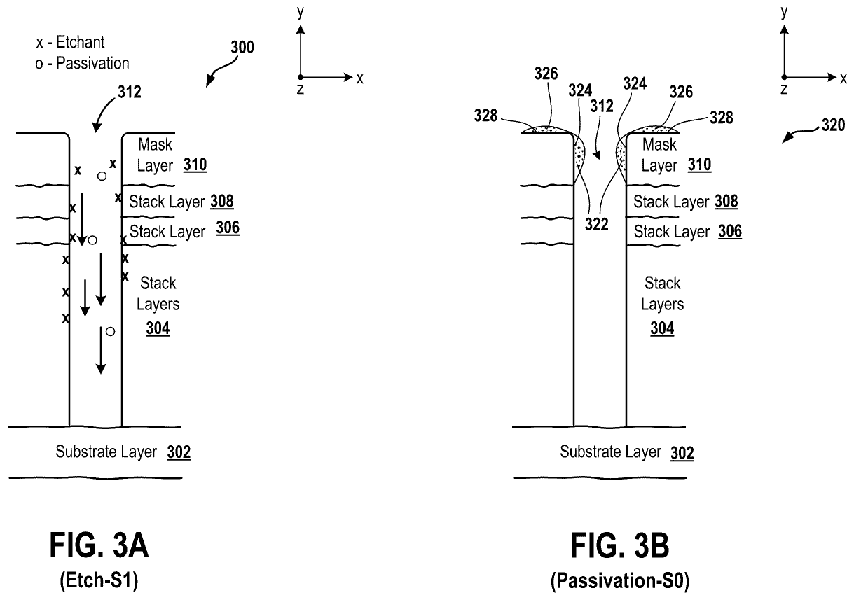

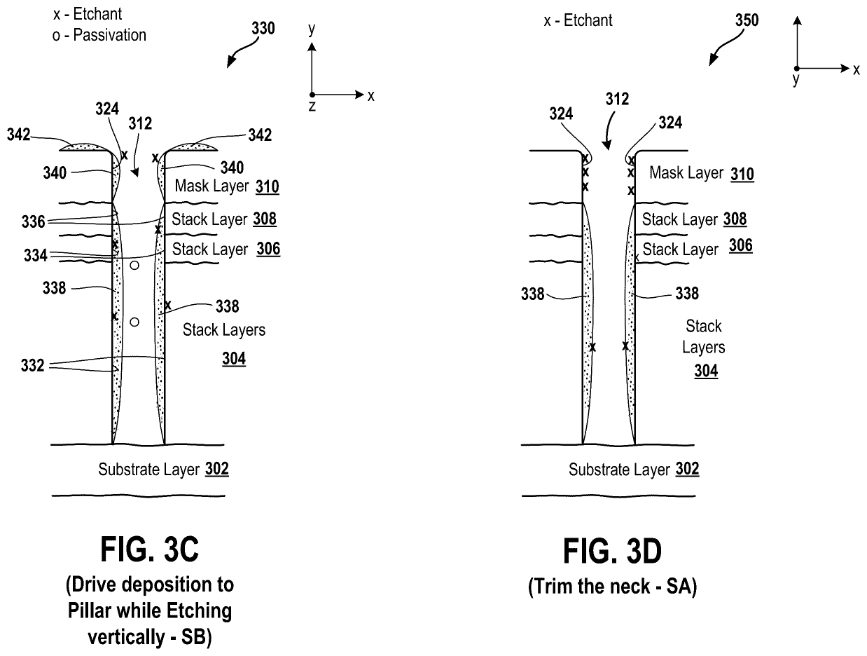

FIG. 3A is a side view of an embodiment of a portion 300 of the substrate S to illustrate an effect of application of the state S1 of the RF signal 102 and the state S1 of the RF signal 104 (FIG. 1). The portion 300 includes a substrate layer 302, a plurality of stack layers 304, a stack layer 306, another stack layer 308, and a mask layer 310. As an example, the substrate layer 302 is silicon. Also, as an example, the stack layers 304 is a series of alternating silicon oxide and polysilicon (OPOP) layers or a series of alternating silicon oxide and silicon nitride (ONON) layers or a layer of silicon oxide. Moreover, as an example, the stack layer 306 is a drain select gate (SGD) layer of polysilicon and the stack layer 308 is a nitride layer or an oxide layer. Also, as an example, the mask layer 310 is an aluminum nitride (AIN) layer or a silicon nitride layer or a silicon oxide layer.

The stack layers 304 are situated above and adjacent to the substrate layer 302. Also, the stack layer 306 is located above and adjacent to the stack layers 304, and the stack layer 308 is located above and adjacent to the stack layer 306. The mask layer 310 is adjacent to and above the stack layer 308. The mask layer 310, the stack layer 308, the stack layer 306, and the stack layers 304 are stacked in a vertical direction along a y-axis. The y-axis is perpendicular to an x-axis and a z-axis. The x-axis is located in a horizontal direction. The z-axis is perpendicular to the y-axis.

During the time period in which the power level of the state S1 of the RF signal 102 and the state S1 of the RF signal 104 are generated, an etchant, such as a chemical, is produced in the gap 126 when the one or more process gases interact with the modified RF signal 142. The etchant is represented as “x” in FIG. 3A and is an example of at least a portion of the plasma generated within the gap 126. The etchant creates, such as etches, features in the stack layers 304, 306, and 308. An example of one of the features is a channel 312 that extends downward in the vertical direction within the stack layers 304, 306, and 308. Moreover, during the time period in which the power level of the state S1 of the RF signal 102 and the state S1 of the RF signal 104 are generated, a small amount of passivation moves down vertically in the channel 312. The passivation is illustrated using “o”s in FIG. 3A. Also, as an example, a passivation, as described herein, is a deposition of a dielectric layer, such as a silicon layer or a silicon-containing layer, due to etching of one or more of the stack layers 304, the stack layer 306, and the stack layer 308.

In one embodiment, the substrate S includes more or less than a number of stack layers 304, 306, and 308 illustrated in FIG. 3A.

FIG. 3B is a diagram of an embodiment of a portion 320 of the substrate S to illustrate passivation during the state S0 of the RF signal 102 and the state S0 of the RF signal 104 (FIG. 1). The portion 320 has the substrate layer 302, the stack layers 304, the stack layer 306, the stack layer 308, and the mask layer 310. Moreover, because of the application of the power level of the state S0 of the RF signal 102 and the power level of the state S0 of the RF signal 104, passivation 322 occurs adjacent to and on a side wall 324 of the mask layer 310 and passivation 326 occurs on a top surface 328 of the mask layer 310. For example, the passivation 322 occurs in a direction of the x-axis from a surface of the side wall 324. In the example, the passivation 326 occurs in a direction of the y-axis from the top surface 328. As an example, the side wall 324 surrounds a portion of the channel 312 laterally, along the x-axis and the z-axis to form a tubular structure around the portion of the channel 312. Also, as an example, each passivation 322 and 326 is a deposition of a dielectric layer, such as a silicon layer or a silicon-containing layer, due to etching of one or more of the stack layers 304, the stack layer 306, and the stack layer 308. For example, atoms of a dielectric material, such as silicon, are output due to etching of the channel 312, and these atoms deposit to form the passivation 322 or 326.

FIG. 3C is a diagram of an embodiment of a portion 330 of the substrate S to illustrate that some of the passivation 322 (FIG. 3B) is driven down by application of the power level of the state SB of the RF signal 102 and the power level of the state SB of the RF signal 104 (FIG. 1). The portion 330 has the substrate layer 302, the stack layers 304, the stack layer 306, the stack layer 308, and the mask layer 310. During the time period in which the plasma is generated or maintained in the gap 126 due to the application of the state SB of the RF signal 102 and the state SB of the RF signal 104, at least a portion of the passivation 322 (FIG. 3B) is driven down vertically, along the y-axis, within the channel 312 to be deposited on side walls 332 of the stack layers 304, a side wall 334 of the stack layer 306, and a side wall 336 of the stack layer 308. The side walls 332, 334, and 336 form a pillar of the channel 312 and the side wall 324 forms a neck of the channel 312. For example, the pillar of the channel 312 includes the side walls 332, 334, and 336 and the neck of the channel 312 includes the side wall 324. The deposition of some of the passivation 322 on the pillar forms a passivation 338 adjacent to the side walls 332, 334, and 336. For example, the passivation 338 is formed in the direction along the x-axis adjacent to the side walls 332, 334, and 336 to reduce a width of the channel 312 adjacent to the side walls 332, 334, and 334 and increase a width of the channel 312 at the neck. A width of the channel 312 is an example of a critical dimension (CD) measured in a horizontal direction along the x-axis. It should be noted that there is a reduction in an amount of the passivation 322 (FIG. 3B) adjacent to the sidewall 324 of the mask layer 310 to achieve a passivation 340 adjacent to the side wall 324. For example, the amount of passivation 340 is less than the amount of passivation 322.

The application of the state SB of the RF signal 102 and the state SB of the RF signal 104 hardens the passivation 326 (FIG. 3B) to a passivation 342. In addition, the application of the state SB of the RF signal 102 and the state SB of the RF signal 104 etches the features within the substrate S vertically further downwards, along the y-axis, compared to the state S1. For example, when a portion of the passivation 322 (FIG. 3B) is driven downwards in the vertical direction, the passivation 338 is formed. By driving the portion of the passivation 322 downward, a critical dimension, such as a width along the x-axis, increases at the neck to allow for an increase in an etch rate of etching the features of the substrate S. Also, the passivation 338 protects the pillar of the substrate S from being etched and increases the etch rate.

FIG. 3D is a diagram of an embodiment of a portion 350 of the substrate S to illustrate that by applying the state SA of the RF signal 102 (FIG. 1) and the state SA of the RF signal 104 (FIG. 1), the passivation 340 (FIG. 3C) reduces to substantially zero. For example, there is no passivation adjacent to the side wall 324 of the mask layer 310. As another example, less than 5 percent of the passivation 340 remains on the side wall 324 during or after application of the SA of the RF signal 102 and the state SA of the RF signal 104. As such, the passivation 340 is trimmed from the sidewall 324 of the neck of the channel 312. Due to the trimming, the CD at the neck of the substrate S increases to increase an etch rate of etching the substrate S. For example, the CD at the neck increases to prepare for the state S1 of the RF signal 102 during an immediately following cycle of the clock signal.

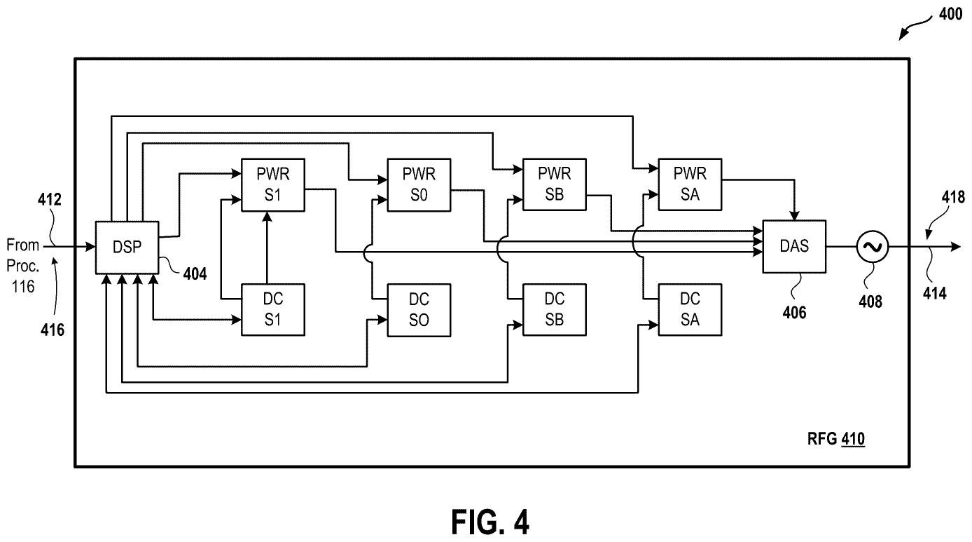

FIG. 4 is a diagram of an embodiment of a system 400 to illustrate details of an operation of an RF generator 410, which is an example of the RF generator 108 or of the RF generator 110 (FIG. 1). The RF generator 410 includes a digital signal processor (DSP) 404 and multiple controllers.

The controllers of the RF generator 410 include a power controller PWRS1, a power controller PWRS0, a power controller PWRSB, and a power controller PWRSA. Also, the controllers of the RF generator 410 include a duty cycle controller DCS1, another duty cycle controller DCS0, a duty cycle controller DCSB, and a duty cycle controller DCSA. Moreover, the RF generator 410 includes a driver amplifier system (DAS) 406, and an RF power supply 408.

Examples of the DSP 404 include an integrated circuit chip and a controller. The DAS 406 includes a driver and an amplifier. Examples of a driver, as described herein, include one or more transistors. An example of an RF power supply, as described herein, is an RF oscillator, which is an electronic circuit that produces periodic oscillating signals at a radio frequency, such as the high or low radio frequency.

The DSP 404 is coupled via a transfer cable 412 to the processor 116. The transfer cable 412 is an example of the transfer cable 128 or of the transfer cable 130 (FIG. 1). The DSP 404 is coupled to the power controllers PWRS1, PWRS0, PWRSB, and PWRSA. Also, the DSP 404 is coupled to the duty cycle controllers DCS1, DCS0, DCSB, and DCSA. The duty cycle controller DCS1 is coupled to the power controller PWRS1. Similarly, the duty cycle controller DCS0 is coupled to the power controller PWRS0, the duty cycle controller DCSB is coupled to the power controller PWRSB, and the duty cycle controller DCSA is coupled to the power controller PWRSA. The power controllers PWRS1, PWRS0, PWRSB, and PWRSA are coupled to the driver of the DAS 406. The driver of the DAS 406 is coupled to the amplifier of the DAS 406, and the amplifier is coupled to the RF power supply 408.

The RF power supply 408 is coupled to an RF cable 414, which is an example of the RF cable 132 or the RF cable 134 (FIG. 1). The DSP 404 receives a recipe signal 416 via the transfer cable 412, obtains the data for generating an RF signal 418 from the recipe signal 416, and stores the data for generating the RF signal 418 within a memory device of the DSP 404. The recipe signal 416 is an example of the recipe signal 138 or the recipe signal 140 (FIG. 1). Also, the RF signal 418 is an example of the RF signal 102 or the RF signal 104 (FIG. 1). The DSP 404 parses the data for generating the RF signal 418 to identify the power level of the state S1 of the RF signal 418, the power level of the state S0 of the RF signal 418, the power level of the state SB of the RF signal 418, and the power level of the state SA of the RF signal 418. Moreover, the DSP 404 parses the data for generating the RF signal 418 to identify the duty cycle of the state S1 of the RF signal 418, the duty cycle of the state S0 of the RF signal 418, the duty cycle of the state SB of the RF signal 418, and the duty cycle of the state SA of the RF signal 418. Also, the DSP 404 parses the data for generating the RF signal 418 to identify the frequency level, such as the low frequency or the high frequency, of the RF signal 418.

The DSP 404 sends the power level of the state S1 of the RF signal 418 to the power controller PWRS1, sends the power level of the state S0 of the RF signal 418 to the power controller PWRS0, sends the power level of the state SB of the RF signal 418 to the power controller PWRSB, and sends the power level of the state SA of the RF signal 418 to the power controller PWRSA. A processor of the power controller PWRS1 stores the power level of the state S1 of the RF signal 418 within a memory device of the power controller PWRS1. Similarly, a processor of the power controller PWRS0 stores the power level of the state S0 of the RF signal 418 within a memory device of the power controller PWRS0, a processor of the power controller PWRSB stores the power level of the state SB of the RF signal 418 within a memory device of the power controller PWRSB, and a processor of the power controller PWRSA stores the power level of the state SA of the RF signal 418 within a memory device of the power controller PWRSA.

Also, the DSP 404 sends the duty cycle of the state S1 of the RF signal 418 to the duty cycle controller DCS1, sends the duty cycle of the state S0 of the RF signal 418 to the duty cycle controller DCS0, sends the duty cycle of the state SB of the RF signal 418 to the duty cycle controller DCSB, and sends the duty cycle of the state SA of the RF signal 418 to the duty cycle controller DCSA. A processor of the duty cycle controller DCS1 stores the duty level of the state S1 of the RF signal 418 within a memory device of the duty cycle controller DCS1. Similarly, a processor of the duty cycle controller DCS0 stores the duty level of the state S0 of the RF signal 418 within a memory device of the duty cycle controller DCS0, a processor of the duty cycle controller DCSB stores the duty cycle of the state SB of the RF signal 418 within a memory device of the duty cycle controller DCSB, and a processor of the duty cycle controller DCSA stores the duty cycle of the state SA of the RF signal 418 within a memory device of the duty cycle controller DCSA.

Moreover, the DSP 404 sends the frequency level of the RF signal 418 to each of the power controllers PWRS1, PWRS0, PWRSB, and PWRSA. The processor of the power controller PWRS1 stores the frequency level of the RF signal 418 within the memory device of the power controller PWRS1. Similarly, the processor of the power controller PWRS0 stores the frequency level of the RF signal 418 within the memory device of the power controller PWRS0, the processor of the power controller PWRSB stores the frequency level of the RF signal 418 within the memory device of the power controller PWRSB, and the processor of the power controller PWRSA stores the frequency level of the RF signal 418 within the memory device of the power controller PWRSA.

In response to receiving the trigger signal from the processor 116, the DSP 404 executes a recipe received within the recipe signal 416. For example, upon receiving the trigger signal, the DSP 404 sends a control signal to the duty cycle controller DCS1 to control the power controller PWRS1. In response to receiving the control signal from the DSP 404, the duty cycle controller DCS1 generates an on duty cycle control signal for the state S1 of the RF signal 418 and sends the on duty cycle control signal to the power controller PWRS1. Upon receiving the on duty cycle control signal for the state S1 of the RF signal 418, the processor of the power controller PWRS1 accesses the power level for the state S1 of the RF signal 418 and the frequency level from the memory device of the power controller PWRS1, and generates an on instruction signal indicating the power level and the frequency level. The processor of the power controller PWRS1 sends the on instruction signal to the DAS 406. In response to receiving the on instruction signal indicating the power level for the state S1 of the RF signal 418 and the frequency level, the driver of the DAS 406 generates a current signal according to the power level for the state S1 of the RF signal 418 and the frequency level of the RF signal 418, and sends the current signal to the amplifier of the DAS 406. The amplifier of the DAS 406 amplifies, such as increases a magnitude of, the current signal to output an amplified current signal, and sends the amplified current signal to the RF power supply 408 to drive the RF power supply 408. Upon receiving the amplified current signal for the state S1 of the RF signal 418, the RF power supply 408 generates the power level of the state S1 of the RF signal 418 and the frequency level of the RF signal 418.

Moreover, in the example, the processor of the duty cycle controller DCS1 includes a time counter that starts counting at a time the on duty cycle control signal is sent to the power controller PWRS1. Based on the count, the processor of the duty cycle controller DCS1 determines that the time period of the state S1 of the RF signal 418 has ended, and upon determining so, the processor of the duty cycle controller DCS1 generates an off duty cycle control signal. The processor of the duty cycle controller DCS1 sends the off duty cycle control signal for the state S1 of the RF signal 418 to the power controller PWRS1 and to the DSP 404. Until the off duty cycle control signal for the state S1 is sent to the power controller PWRS1, the RF power supply 408 continues to generate the power level of the state S1 of the RF signal 418.

Upon receiving the off duty cycle control signal for the state S1 of the RF signal 418, the processor of the power controller PWRS1 generates an off instruction signal. The processor of the power controller PWRS1 sends the off instruction signal to the DAS 406. In response to receiving the off instruction signal, the DAS 406 stops generating the amplified current signal according to the power level for the state S1 of the RF signal 418, and the RF power supply 408 discontinues generating the power level of the state S1 of the RF signal 418.

Also, in the example, in response to receiving the off duty cycle control signal for the state S1 from the processor of the duty cycle controller DCS1, the DSP 404 sends a control signal to the duty cycle controller DCS0 to control the power controller PWRS0. In response to receiving the control signal from the DSP 404, the duty cycle controller DCS0 generates an on duty cycle control signal for the state S0 of the RF signal 418 and sends the on duty cycle control signal to the power controller PWRS0. Upon receiving the on duty cycle control signal for the state S0 of the RF signal 418, the processor of the power controller PWRS0 accesses the power level for the state S0 of the RF signal 418 and the frequency level from the memory device of the power controller PWRS0, and generates an on instruction signal indicating the power level and the frequency level. The processor of the power controller PWRS0 sends the on instruction signal to the DAS 406. In response to receiving the on instruction signal, the driver of the DAS 406 generates a current signal according to the power level for the state S0 of the RF signal 418 and the frequency level, and sends the current signal to the amplifier of the DAS 406. The amplifier of the DAS 406 amplifies, such as increases a magnitude of, the current signal to output an amplified current signal, and sends the amplified current signal to the RF power supply 408 to drive the RF power supply 408. Upon receiving the amplified current signal for the state S0 of the RF signal 418, the RF power supply 408 generates the power level of the state S0 of the RF signal 418 and the frequency level of the RF signal 418.

It should be noted that in the example, when the power level for the state S0 of the RF signal 418 is zero, the processor of the power controller PWRS0 does not generate and does not send the on instruction signal to the DAS 406, and the DAS 406 does not generate the current signal. When the current signal is not generated, the RF power supply 408 outputs the power level of the state S0 of the RF signal 418 to be zero.

Moreover, in the example, the processor of the duty cycle controller DCS0 includes a time counter that starts counting at a time the on duty cycle control signal is sent to the power controller PWRS0. Based on the count, the processor of the duty cycle controller DCS0 determines that the time period of the state S0 of the RF signal 418 has ended, and upon determining so, the processor of the duty cycle controller DCS0 generates an off duty cycle control signal. The processor of the duty cycle controller DCS0 sends the off duty cycle control signal for the state S0 of the RF signal 418 to the power controller PWRS0 and to the DSP 404. Until the off duty cycle control signal for the state S0 is sent to the power controller PWRS0, the RF power supply 408 continues to generate or output the power level of the state S0 of the RF signal 418.

Upon receiving the off duty cycle control signal for the state S0 of the RF signal 418, the processor of the power controller PWRS0 generates an off instruction signal. The processor of the power controller PWRS0 sends the off instruction signal to the DAS 406. In response to receiving the off instruction signal, the DAS 406 stops generating the amplified current signal according to the power level for the state S0 of the RF signal 418, and the RF power supply 408 discontinues generating the power level of the state S0 of the RF signal 418.

Further, in the example, in response to receiving the off duty cycle control signal for the state S0 from the processor of the duty cycle controller DCS0, the DSP 404 sends a control signal to the duty cycle controller DCSB to facilitate control of the power controller PWRSB. In response to receiving the control signal from the DSP 404, the duty cycle controller DCSB generates an on duty cycle control signal for the state SB of the RF signal 418 and sends the on duty cycle control signal to the power controller PWRSB. Upon receiving the on duty cycle control signal for the state SB of the RF signal 418, the processor of the power controller PWRSB accesses the power level for the state SB of the RF signal 418 and the frequency level of the RF signal 418 from the memory device of the power controller PWRSB, and generates an on instruction signal indicating the power level for the state SB and the frequency level. The processor of the power controller PWRSB sends the on instruction signal to the DAS 406. In response to receiving the on instruction signal, the driver of the DAS 406 generates a current signal according to the power level for the state SB of the RF signal 418 and the frequency level of the RF signal 418, and sends the current signal to the amplifier of the DAS 406. The amplifier of the DAS 406 amplifies, such as increases a magnitude of, the current signal to output an amplified current signal, and sends the amplified current signal to the RF power supply 408 to drive the RF power supply 408. Upon receiving the amplified current signal for the state SB of the RF signal 418, the RF power supply 408 generates the power level of the state SB of the RF signal 418 and the frequency level of the RF signal 418.

Moreover, in the example, the processor of the duty cycle controller DCSB includes a time counter that starts counting at a time the on duty cycle control signal is sent to the power controller PWRSB. Based on the count, the processor of the duty cycle controller DCSB determines that the time period of the state SB of the RF signal 418 has ended, and upon determining so, the processor of the duty cycle controller DCSB generates an off duty cycle control signal. The processor of the duty cycle controller DCSB sends the off duty cycle control signal for the state SB of the RF signal 418 to the power controller PWRSB and to the DSP 404. Until the off duty cycle control signal for the state SB is sent to the power controller PWRSB, the RF power supply 408 continues to generate the power level of the state SB of the RF signal 418.

Upon receiving the off duty cycle control signal for the state SB of the RF signal 418, the processor of the power controller PWRSB generates an off instruction signal. The processor of the power controller PWRSB sends the off instruction signal to the DAS 406. In response to receiving the off instruction signal, the DAS 406 stops generating the amplified current signal according to the power level for the state SB of the RF signal 418, and the RF power supply 408 discontinues generating the power level of the state SB of the RF signal 418.

Also, in the example, in response to receiving the off duty cycle control signal for the state SB from the processor of the duty cycle controller DCSB, the DSP 404 sends a control signal to the duty cycle controller DCSA to control the power controller PWRSA. In response to receiving the control signal from the DSP 404, the duty cycle controller DCSA generates an on duty cycle control signal for the state SA of the RF signal 418 and sends the on duty cycle control signal to the power controller PWRSA. Upon receiving the on duty cycle control signal for the state SA of the RF signal 418, the processor of the power controller PWRSA accesses the power level for the state SA of the RF signal 418 and the frequency level of the RF signal 418 from the memory device of the power controller PWRSA, and generates an on instruction signal indicating the power level and the frequency level. The processor of the power controller PWRSA sends the on instruction signal to the DAS 406. In response to receiving the on instruction signal, the driver of the DAS 406 generates a current signal according to the power level for the state SA of the RF signal 418 and the frequency level of the RF signal 418, and sends the current signal to the amplifier of the DAS 406. The amplifier of the DAS 406 amplifies, such as increases a magnitude of, the current signal to output an amplified current signal, and sends the amplified current signal to the RF power supply 408 to drive the RF power supply 408. Upon receiving the amplified current signal for the state SA of the RF signal 418, the RF power supply 408 generates the power level of the state SA of the RF signal 418 and the frequency level of the RF signal 418.

It should be noted that in the example, when the power level for the state SA of the RF signal 418 is zero, the processor of the power controller PWRSA does not generate and does not send the on instruction signal to the DAS 406, and the DAS 406 does not generate the current signal. When the current signal is not generated, the RF power supply 408 outputs the power level of the state SA of the RF signal 418 to be zero.

Moreover, in the example, the processor of the duty cycle controller DCSA includes a time counter that starts counting at a time the on duty cycle control signal is sent to the power controller PWRSA. Based on the count, the processor of the duty cycle controller DCSA determines that the time period of the state SA of the RF signal 418 has ended, and upon determining so, the processor of the duty cycle controller DCSA generates an off duty cycle control signal. The processor of the duty cycle controller DCSA sends the off duty cycle control signal for the state SA of the RF signal 418 to the power controller PWRSA and to the DSP 404. Until the off duty cycle control signal for the state SA is sent to the power controller PWRSA, the RF power supply 408 continues to generate the power level of the state SA of the RF signal 418.

Upon receiving the off duty cycle control signal for the state SA of the RF signal 418, the processor of the power controller PWRSA generates an off instruction signal. The processor of the power controller PWRSA sends the off instruction signal to the DAS 406. In response to receiving the off instruction signal, the DAS 406 stops generating the amplified current signal according to the power level for the state SA of the RF signal 418, and the RF power supply 408 discontinues generating the power level of the state SA of the RF signal 418.

Moreover, in the example, in response to receiving the off duty cycle control signal for the state SA from the processor of the duty cycle controller DCSB and determining that the clock signal received from the processor 116 via the transfer cable 412 indicates an end of the cycle 1 and a beginning of the cycle 2 of the clock signal, the DSP 404 repeats sending a control signal to the duty cycle controller DCS1 to control the power controller PWRS1 to repeat the state S1 of the RF signal 418 during the cycle 2 of the clock signal. Furthermore, during the cycle 2, the states S0, SB, and SA are repeated in the same manner as that during the cycle 1 of the clock signal.

In one embodiment, one or more controllers are used instead of the DSP 404, the power controllers PWRS1, PWRS0, PWRSB, and PWRSA, and the duty cycle controllers DCS1, DCS0, DCSB, and DCSA. For example, a single controller executes the functions, described herein, as performed by the DSP 404, the power controllers PWRS1, PWRS0, PWRSB, and PWRSA, and the duty cycle controllers DCS1, DCS0, DCSB, and DCSA. As another example, a single controller executes the functions, described herein, as performed the power controllers PWRS1, PWRS0, PWRSB, and PWRSA. As yet another example, a single controller executes the functions, described herein, as performed by the duty cycle controllers DCS1, DCS0, DCSB, and DCSA.

Embodiments described herein may be practiced with various computer system configurations including hand-held hardware units, microprocessor systems, microprocessor-based or programmable consumer electronics, minicomputers, mainframe computers and the like. The embodiments can also be practiced in distributed computing environments where tasks are performed by remote processing hardware units that are linked through a network.

In some embodiments, a controller is part of a system, which may be part of the above-described examples. Such systems include semiconductor processing equipment, including a processing tool or tools, chamber or chambers, a platform or platforms for processing, and/or specific processing components (a wafer pedestal, a gas flow system, etc.). These systems are integrated with electronics for controlling their operation before, during, and after processing of a semiconductor wafer or substrate. The electronics is referred to as the “controller,” which may control various components or subparts of the system or systems. The controller, depending on the processing requirements and/or the type of system, is programmed to control any of the processes disclosed herein, including the delivery of process gases, temperature settings (e.g., heating and/or cooling), pressure settings, vacuum settings, power settings, RF generator settings, RF matching circuit settings, frequency settings, flow rate settings, fluid delivery settings, positional and operation settings, wafer transfers into and out of a tool and other transfer tools and/or load locks coupled to or interfaced with a system.

Broadly speaking, in a variety of embodiments, the controller is defined as electronics having various integrated circuits, logic, memory, and/or software that receive instructions, issue instructions, control operation, enable cleaning operations, enable endpoint measurements, and the like. The integrated circuits include chips in the form of firmware that store program instructions, digital signal processors (DSPs), chips defined as ASICs, PLDs, and/or one or more microprocessors, or microcontrollers that execute program instructions (e.g., software). The program instructions are instructions communicated to the controller in the form of various individual settings (or program files), defining the parameters, the factors, the variables, etc., for carrying out a particular process on or for a semiconductor wafer or to a system. The program instructions are, in some embodiments, a part of a recipe defined by process engineers to accomplish one or more processing steps during the fabrication of one or more layers, materials, metals, oxides, silicon, silicon dioxide, surfaces, circuits, and/or dies of a wafer.

The controller, in some embodiments, is a part of or coupled to a computer that is integrated with, coupled to the system, otherwise networked to the system, or a combination thereof. For example, the controller is in a “cloud” or all or a part of a fab host computer, which allows for remote access of the wafer processing. The computer enables remote access to the system to monitor current progress of fabrication operations, examines a history of past fabrication operations, examines trends or performance metrics from a plurality of fabrication operations, to change parameters of current processing, to set processing steps to follow a current processing, or to start a new process.

In some embodiments, a remote computer (e.g. a server) provides process recipes to a system over a network, which includes a local network or the Internet. The remote computer includes a user interface that enables entry or programming of parameters and/or settings, which are then communicated to the system from the remote computer. In some examples, the controller receives instructions in the form of data, which specify the parameters, factors, and/or variables for each of the processing steps to be performed during one or more operations. It should be understood that the parameters, factors, and/or variables are specific to the type of process to be performed and the type of tool that the controller is configured to interface with or control. Thus as described above, the controller is distributed, such as by including one or more discrete controllers that are networked together and working towards a common purpose, such as the processes and controls described herein. An example of a distributed controller for such purposes includes one or more integrated circuits on a chamber in communication with one or more integrated circuits located remotely (such as at the platform level or as part of a remote computer) that combine to control a process on the chamber.

Without limitation, in various embodiments, example systems to which the methods are applied include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that is associated or used in the fabrication and/or manufacturing of semiconductor wafers.

It is further noted that in some embodiments, the above-described operations apply to several types of plasma chambers, e.g., a plasma chamber including an inductively coupled plasma (ICP) reactor, a transformer coupled plasma chamber, conductor tools, dielectric tools, a plasma chamber including an electron cyclotron resonance (ECR) reactor, etc. For example, one or more RF generators are coupled to an inductor within the ICP reactor. Examples of a shape of the inductor include a solenoid, a dome-shaped coil, a flat-shaped coil, etc.

As noted above, depending on the process step or steps to be performed by the tool, the host computer communicates with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

With the above embodiments in mind, it should be understood that some of the embodiments employ various computer-implemented operations involving data stored in computer systems. These operations are those physically manipulating physical quantities. Any of the operations described herein that form part of the embodiments are useful machine operations.

Some of the embodiments also relate to a hardware unit or an apparatus for performing these operations. The apparatus is specially constructed for a special purpose computer. When defined as a special purpose computer, the computer performs other processing, program execution or routines that are not part of the special purpose, while still being capable of operating for the special purpose.

In some embodiments, the operations may be processed by a computer selectively activated or configured by one or more computer programs stored in a computer memory, cache, or obtained over the computer network. When data is obtained over the computer network, the data may be processed by other computers on the computer network, e.g., a cloud of computing resources.

One or more embodiments can also be fabricated as computer-readable code on a non-transitory computer-readable medium. The non-transitory computer-readable medium is any data storage hardware unit, e.g., a memory device, etc., that stores data, which is thereafter be read by a computer system. Examples of the non-transitory computer-readable medium include hard drives, network attached storage (NAS), ROM, RAM, compact disc-ROMs (CD-ROMs), CD-recordables (CD-Rs), CD-rewritables (CD-RWs), magnetic tapes and other optical and non-optical data storage hardware units. In some embodiments, the non-transitory computer-readable medium includes a computer-readable tangible medium distributed over a network-coupled computer system so that the computer-readable code is stored and executed in a distributed fashion.

Although the method operations above were described in a specific order, it should be understood that in various embodiments, other housekeeping operations are performed in between operations, or the method operations are adjusted so that they occur at slightly different times, or are distributed in a system which allows the occurrence of the method operations at various intervals, or are performed in a different order than that described above.

It should further be noted that in an embodiment, one or more features from any embodiment described above are combined with one or more features of any other embodiment without departing from a scope described in various embodiments described in the present disclosure.

Although the foregoing embodiments have been described in some detail for purposes of clarity of understanding, it will be apparent that certain changes and modifications can be practiced within the scope of appended claims. Accordingly, the present embodiments are to be considered as illustrative and not restrictive, and the embodiments are not to be limited to the details given herein.

1. A method for driving passivation to increase a rate of etching a substrate, comprising:
generating a kilohertz radio frequency (RF) signal;
generating a megahertz RF signal;
supplying the kilohertz and megahertz RF signals to an impedance matching circuit coupled to an electrode of a plasma chamber;
during a clock cycle of a clock signal,
pulsing, in a synchronized manner, the kilohertz and megahertz RF signals to transition to a first state to etch the substrate;
maintaining the kilohertz and megahertz RF signals in the first state for a first predetermined time period;
transitioning, in a synchronized manner, the kilohertz and megahertz RF signals from the first state to a second state to achieve passivation on a side wall and a top surface of a mask layer of the substrate;
maintaining the kilohertz and megahertz RF signals in the second state for a second predetermined time period that is greater than the first predetermined time period, wherein during the second state, a power level of the kilohertz RF signal is less than a power level of the kilohertz RF signal during the first state and a power level of the megahertz RF signal is less than a power level of the megahertz RF signal during the first state;
pulsing, in a synchronized manner, the kilohertz and megahertz RF signals from the second state to a third state to drive the passivation from a neck of the substrate to a pillar of the substrate;
maintaining the kilohertz and megahertz RF signals in the third state for a third predetermined time period that is substantially equal to the first predetermined time period, wherein during the third state, a power level of the kilohertz RF signal is greater than the power level of the kilohertz RF signal during the second state and a power level of the megahertz RF signal is greater than the power level of the megahertz RF signal during the second state;
transitioning, in a synchronized manner, the kilohertz and megahertz RF signals from the third state to a fourth state to reduce the passivation from the neck of the substrate; and
maintaining the kilohertz and megahertz RF signals in the fourth state for a fourth predetermined time period that is greater than the third predetermined time period, wherein during the fourth state, a power level of the kilohertz RF signal is less than the power level of the kilohertz RF signal during the third state and a power level of the megahertz RF signal is less than the power level of the megahertz RF signal during the third state.

2. The method of claim 1, wherein the power level of the kilohertz RF signal during each of the first and third states ranges from 1 kilowatts to 100 kilowatts to etch the substrate and the power level of the megahertz RF signal during each of the first and third states ranges from 1 kilowatt to 11 kilowatts to etch the substrate.

3. The method of claim 2, wherein the power level of the kilohertz RF signal during the first state is equal to the power level of the kilohertz RF signal during the third state to etch the substrate and the power level of the megahertz RF signal during the first state is equal to the power level of the megahertz RF signal during the third state to etch the substrate.

4. The method of claim 1, wherein the power level of each of the kilohertz RF signal and the megahertz RF signal is substantially zero during the second state to achieve the passivation.

5. The method of claim 4, wherein the power level of each of the kilohertz RF signal and the megahertz RF signal during the second state ranges from 0 watts to 200 watts to achieve the passivation.

6. The method of claim 1, wherein the power level of the kilohertz RF signal is zero during the fourth state and the power level of the megahertz RF signal ranges from 200 watts to 1000 watts during the fourth state to reduce the passivation from the neck of the substrate.

7. The method of claim 1, wherein the first predetermined time period ranges from 5 percent to 20 percent of the clock cycle, the second predetermined time period ranges from 20 to 60 percent of the clock cycle, the third predetermined time period ranges from 5 percent to 20 percent of the clock cycle, and the fourth predetermined time period ranges from 20 to 60 percent of the clock cycle such that a sum of the first through fourth time periods is 100 percent of the clock cycle.

8. The method of claim 7, wherein the first predetermined time period is 5 percent of the clock cycle, the second predetermined time period is 60 percent of the clock cycle, the third predetermined time period is 5 percent of the clock cycle, and the fourth predetermined time period is 30 percent of the clock cycle.

9. The method of claim 1, wherein the third state of the megahertz RF signal facilitates an increase a power level of the megahertz RF signal during the fourth state from a first range to a second range, wherein the second range facilitates an increase in ion density of plasma within the plasma chamber compared to the first range to increase a stability of the plasma, wherein the second range is applied for lesser time period compared to an application of the first range, wherein the lesser time period is the fourth predetermined time period.

10. The method of claim 9, wherein the first range is a range from 0 watts to 200 watts, and the second range is a range from 200 watts to 1000 watts.

11. The method of claim 1, wherein the first predetermined time period is equal to the third predetermined time period to etch the substrate and the second predetermined time period is greater than the fourth predetermined time period to achieve the passivation.

12. A controller for driving passivation to increase a rate of etching a substrate, comprising:
a processor configured to:
control a first radio frequency (RF) generator to generate a kilohertz RF signal;
control a second RF generator to generate a megahertz RF signal,
wherein during a clock cycle of a clock signal, the processor is configured to control the first and second RF generators to:
pulse, in a synchronized manner, the kilohertz and megahertz RF signals to transition to a first state;
maintain the kilohertz and megahertz RF signals in the first state for a first predetermined time period;
transition, in a synchronized manner, the kilohertz and megahertz RF signals from the first state to a second state;
maintain the kilohertz and megahertz RF signals in the second state for a second predetermined time period that is greater than the first predetermined time period, wherein during the second state, a power level of the kilohertz RF signal is less than a power level of the kilohertz RF signal during the first state and a power level of the megahertz RF signal is less than a power level of the megahertz RF signal during the first state;
pulse, in a synchronized manner, the kilohertz and megahertz RF signals from the second state to a third state;
maintain the kilohertz and megahertz RF signals in the third state for a third predetermined time period that is substantially equal to the first predetermined time period, wherein during the third state, a power level of the kilohertz RF signal is greater than the power level of the kilohertz RF signal during the second state and a power level of the megahertz RF signal is greater than the power level of the megahertz RF signal during the second state;
transition, in a synchronized manner, the kilohertz and megahertz RF signals from the third state to a fourth state; and
maintain the kilohertz and megahertz RF signals in the fourth state for a fourth predetermined time period that is greater than the third predetermined time period, wherein during the fourth state, a power level of the kilohertz RF signal is less than the power level of the kilohertz RF signal during the third state and a power level of the megahertz RF signal is less than the power level of the megahertz RF signal during the third state; and
a memory device coupled to the processor.

13. The controller of claim 12, wherein the power level of the kilohertz RF signal during each of the first and third states ranges from 1 kilowatts to 100 kilowatts to etch the substrate and the power level of the megahertz RF signal during each of the first and third states ranges from 1 kilowatt to 11 kilowatts.

14. The controller of claim 13, wherein the power level of the kilohertz RF signal during the first state is equal to the power level of the kilohertz RF signal during the third state to etch the substrate and the power level of the megahertz RF signal during the first state is equal to the power level of the megahertz RF signal during the third state.

15. The controller of claim 12, wherein the power level of each of the kilohertz RF signal and the megahertz RF signal is substantially zero during the second state.

16. The controller of claim 15, wherein the power level of each of the kilohertz RF signal and the megahertz RF signal during the second state ranges from 0 watts to 200 watts.

17. The controller of claim 12, wherein the power level of the kilohertz RF signal is zero during the fourth state and the power level of the megahertz RF signal ranges from 200 watts to 1000 watts during the fourth state.

18. The controller of claim 12, wherein the first predetermined time period ranges from 5 percent to 20 percent of the clock cycle, the second predetermined time period ranges from 20 to 60 percent of the clock cycle, the third predetermined time period ranges from 5 percent to 20 percent of the clock cycle, and the fourth predetermined time period ranges from 20 to 60 percent of the clock cycle such that a sum of the first through fourth time periods is 100 percent of the clock cycle.

19. The controller of claim 17, wherein the first predetermined time period is 5 percent of the clock cycle, the second predetermined time period is 60 percent of the clock cycle, the third predetermined time period is 5 percent of the clock cycle, and the fourth predetermined time period is 30 percent of the clock cycle.

20. A system for driving passivation to increase a rate of etching a substrate, comprising:
a first radio frequency (RF) generator configured to generate a kilohertz RF signal;
a second RF generator configured to generate a megahertz RF signal;
an impedance matching circuit coupled to the first and second RF generators to receive the kilohertz and megahertz RF signals to output a modified RF signal; and
a plasma chamber coupled to the impedance matching circuit to receive the modified RF signal; and
a controller coupled to the first and second RF generators, wherein during a clock cycle of a clock signal, the controller is configured to control the first and second RF generators to:
pulse, in a synchronized manner, the kilohertz and megahertz RF signals to transition to a first state;
maintain the kilohertz and megahertz RF signals in the first state for a first predetermined time period;
transition, in a synchronized manner, the kilohertz and megahertz RF signals from the first state to a second state;
maintain the kilohertz and megahertz RF signals in the second state for a second predetermined time period that is greater than the first predetermined time period, wherein during the second state, a power level of the kilohertz RF signal is less than a power level of the kilohertz RF signal during the first state and a power level of the megahertz RF signal is less than a power level of the megahertz RF signal during the first state;
pulse, in a synchronized manner, the kilohertz and megahertz RF signals from the second state to a third state;
maintain the kilohertz and megahertz RF signals in the third state for a third predetermined time period that is substantially equal to the first predetermined time period, wherein during the third state, a power level of the kilohertz RF signal is greater than the power level of the kilohertz RF signal during the second state and a power level of the megahertz RF signal is greater than the power level of the megahertz RF signal during the second state;
transition, in a synchronized manner, the kilohertz and megahertz RF signals from the third state to a fourth state; and
maintain the kilohertz and megahertz RF signals in the fourth state for a fourth predetermined time period that is greater than the third predetermined time period, wherein during the fourth state, a power level of the kilohertz RF signal is less than the power level of the kilohertz RF signal during the third state and a power level of the megahertz RF signal is less than the power level of the megahertz RF signal during the third state.

21. The system of claim 21, wherein the third state of the megahertz RF signal facilitates an increase a power level of the megahertz RF signal during the fourth state from a first range to a second range, wherein the second range facilitates an increase in ion density of plasma within the plasma chamber compared to the first range to increase a stability of the plasma, wherein the second range is applied for lesser time period compared to an application of the first range, wherein the lesser time period is the fourth predetermined time period.
